(19) United States
(12) Patent Application Publication
(10) Pub. No.: US 2023/0130933 A1
(43) Pub. Date: Apr. 27, 2023

(54) SWITCHING CIRCUIT, DC/DC CONVERTER, AND CONTROL CIRCUIT OF DC/DC CONVERTER

(71) Applicant: ROHM Co., LTD., Kyoto (JP)

(72) Inventor: Shun FUKUSHIMA, Kyoto (JP)

(21) Appl. No.: 18/048,095

(22) Filed: Oct. 20, 2022

(30) Foreign Application Priority Data
Oct. 22, 2021 (JP) 2021-173361

(51) Int. Cl. H02M 3/156; H02M 3/18; H03K 17/30

(52) U.S. Cl. CPC H02M 3/156; H02M 3/18; H03K 17/30; H03K 2017/307

(57) ABSTRACT

Provided is a switching circuit including an input terminal, a switching terminal, a ground terminal, a bootstrap terminal, a high side transistor connected to the input terminal and the switching terminal, a low side transistor connected to the switching terminal and the ground terminal, a bootstrap capacitor connected to the switching terminal and the bootstrap terminal, a bootstrap switch including a PMOS transistor, and a driver circuit that turns on the bootstrap switch in a period in which the low side transistor is on and that turns off the bootstrap switch in a period in which the low side transistor is off, in which the driver circuit includes a level shifter and a buffer, and the level shifter includes an output line, a first resistance, a first transistor, a second resistance, a third resistance, a second transistor, a third transistor, a first capacitor, and a fourth transistor.

### CROSS REFERENCE TO RELATED APPLICATIONS

This application claims priority benefit of Japanese Patent Application No. JP 2021-173361 filed in the Japan Patent Office on Oct. 22, 2021. Each of the above-referenced applications is hereby incorporated herein by reference in its entirety.

### BACKGROUND

The present disclosure relates to a switching circuit.

A switching circuit is used for a direct current/direct current (DC/DC) converter or an inverter, for example. FIG. 1 is a circuit diagram of the switching circuit. A switching circuit 100R includes a high side transistor M1 provided between an input terminal (VIN) and a switching terminal (SW) and a low side transistor M2 provided between the SW terminal and a ground terminal (GND). In a state in which the high side transistor M1 is on and the low side transistor M2 is off, the SW terminal enters a high level (voltage V_{IN} of VIN terminal is generated). In a state in which the high side transistor M1 is off and the low side transistor M2 is on, a low level (voltage V_{GND} of GND terminal) is generated in the SW terminal. Note that a rectifier, such as a Schottky diode, may be provided in place of the low side transistor M2.

An N-channel (or NPN) transistor is used for the high side transistor M1 in some cases. In this case, a gate voltage V_{HG} higher than the input voltage V_{IN} may need to be provided to the gate of the high side transistor M1 in order to turn on the high side transistor M1. A bootstrap circuit is used to generate the gate voltage V_{HG} that is higher than the input voltage V_{IN}.

A bootstrap capacitor C_{BST} is connected to a bootstrap terminal (BST) and the SW terminal. A power supply circuit 110 for the bootstrap circuit generates a constant voltage V_{DD}. The constant voltage V_{DD} is set higher than a threshold voltage V_{GS(th)} between the gate and the source of the high side transistor M1. The constant voltage V_{DD} is applied to the bootstrap capacitor C_{BST} through a diode D1 and the BST terminal.

The bootstrap capacitor C_{BST} is charged at ΔV=V_{DD}−Vf in a state in which the SW terminal is low (0 V). Vf represents a forward voltage of the diode D1. A voltage V_{BST} of the BST terminal is V_{SW}+ΔV. The voltage V_{BST} of the BST terminal is supplied to a power supply terminal on the upper side of a high side driver 102. A ground side terminal of the high side driver 102 is connected to the SW terminal. The high side driver 102 outputs V_{BST} when a control signal S_{H} is in an on level (for example, high) and outputs V_{SW} when the control signal S_{H} is in an off level (for example, low).

### SUMMARY

A bootstrap switch may be used in place of the diode D1. The bootstrap switch is turned on in a period in which the low side transistor M2 is on, and is turned off in a period in which the low side transistor M2 is off.

The bootstrap switch includes a P-channel metal oxide semiconductor (MOS) transistor. In this case, the source of the P-channel MOS transistor is connected to the BST terminal. That is, the source voltage of the P-channel MOS transistor is V_{BST} of the BST terminal, and is changed in conjunction with switching of the switching circuit 100R. A level shifter may be necessary to appropriately drive the P-channel MOS transistor. The bootstrap switch malfunctions if the response speed of the level shifter is slow.

The present disclosure has been made in view of the circumstances, and it is desirable to provide a switching circuit that can appropriately drive a bootstrap switch.

A mode of the present disclosure relates to a switching circuit. The switching circuit includes an input terminal, a switching terminal, a ground terminal, a bootstrap terminal, a high side transistor connected to the input terminal and the switching terminal, a low side transistor connected to the switching terminal and the ground terminal, a bootstrap capacitor connected to the switching terminal and the bootstrap terminal, a bootstrap switch including a PMOS transistor connected to a constant voltage line and the bootstrap terminal, and a driver circuit that turns on the bootstrap switch in a period in which the low side transistor is on and that turns off the bootstrap switch in a period in which the low side transistor is off. The driver circuit includes a level shifter that shifts a level of a control signal, and a buffer that drives the PMOS transistor according to output of the level shifter. The level shifter includes an output line, a first resistance connected to the bootstrap terminal and the output line, a first transistor including a drain connected to the output line, the first transistor being turned on when the control signal is in an on level, a second resistance connected to a source of the first transistor and a ground, a third resistance including a first end connected to the bootstrap terminal, a second transistor including a drain connected to a second end of the third resistance, the second transistor being turned on when the control signal is in an off level, a third transistor connected to a source of the second transistor and the ground and turned on when the control signal is in the on level, a first capacitor connected to the third transistor in parallel, and a fourth transistor including a source connected to the bootstrap terminal, a drain connected to the output line, and a gate connected to a drain of the second transistor.

Note that any combinations of the constituent elements as well as constituent elements and expressions obtained by exchanging the constituent elements and the expressions among methods, apparatuses, and systems are also effective as modes of the present technology.

According to the mode of the present disclosure, the bootstrap switch can appropriately be driven.

### BRIEF DESCRIPTION OF THE DRAWINGS

FIG. 1 is a circuit diagram of a switching circuit;

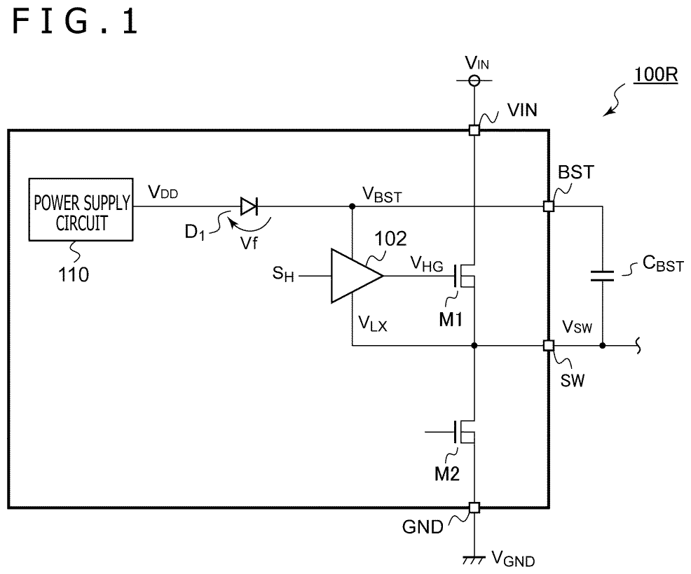

FIG. 2 is a circuit diagram of a switching circuit according to a first embodiment;

FIG. 3 is a circuit diagram of a control circuit according to the embodiment;

FIG. 4 is a circuit diagram of a control circuit according to comparative technique 1;

FIG. 5 is an operation waveform diagram of the control circuit according to comparative technique 1;

FIG. 6 is a circuit diagram of a control circuit according to comparative technique 2;

FIG. 7 is an equivalent circuit diagram of the control circuit when a control signal BST_ON is in an on level;

FIG. 8 is an equivalent circuit diagram of the control circuit when the control signal BST_ON is in an off level;

FIG. 9 is a circuit diagram of a control circuit according to a modification; and

FIG. 10 is a circuit diagram of a DC/DC converter.

### DETAILED DESCRIPTION OF THE PREFERRED EMBODIMENTS

### (Overview of Embodiments)

An overview of some exemplary embodiments of the present disclosure will be described. The overview simply describes some concepts of one or a plurality of embodiments for basic understanding of the embodiments, as a preface to detailed explanation described later, and does not limit the extent of the technology or the disclosure. The overview is not a comprehensive overview of all conceivable embodiments, and is not intended to specify important elements of all the embodiments or to define the scope of part or all of the modes. For convenience, “one embodiment” may be used to represent one embodiment (example or modification) or a plurality of embodiments (examples or modifications) disclosed in the present specification.

A switching circuit according to an embodiment includes an input terminal, a switching terminal, a ground terminal, a bootstrap terminal, a high side transistor connected to the input terminal and the switching terminal, a low side transistor connected to the switching terminal and the ground terminal, a bootstrap capacitor connected to the switching terminal and the bootstrap terminal, a bootstrap switch including a PMOS transistor connected to a constant voltage line and the bootstrap terminal, and a driver circuit that turns on the bootstrap switch in a period in which the low side transistor is on and that turns off the bootstrap switch in a period in which the low side transistor is off. The driver circuit includes a level shifter that shifts a level of a control signal, and a buffer that drives the PMOS transistor according to output of the level shifter. The level shifter includes an output line, a first resistance connected to the bootstrap terminal and the output line, a first transistor including a drain connected to the output line, the first transistor being turned on when the control signal is in an on level, a second resistance connected to a source of the first transistor and a ground, a third resistance including a first end connected to the bootstrap terminal, a second transistor including a drain connected to a second end of the third resistance, the second transistor being turned on when the control signal is in an off level, a third transistor connected to a source of the second transistor and the ground and turned on when the control signal is in the on level, a first capacitor connected to the third transistor in parallel and a fourth transistor including a source connected to the bootstrap terminal, a drain connected to the output line, and a gate connected to a drain of the second transistor.

When the control signal enters the on level (high), the first transistor is turned on. The voltage of the output line becomes low, and the bootstrap switch is turned on. In this case, the second transistor is turned off, and the third transistor is turned on. The first capacitor is discharged, and the voltage of the first capacitor becomes 0. When the control signal is shifted to the off level (low), the first transistor is turned off, and the output line is pulled up by the first resistance. Although the voltage of the output line would rise toward the voltage of the bootstrap terminal when the output line is pulled up by the first resistance, the change rate of the voltage is limited by the resistance value of the first resistance. In the configuration, the third transistor is turned off, and the second transistor is turned on. As a result, the first capacitor is charged. The charge current is supplied from the drain of the second transistor, and the drain voltage of the second transistor, that is, the gate voltage of the fourth transistor, swiftly drops. As a result, the fourth transistor is turned on. The impedance of the fourth transistor is lower than the impedance of the first resistance. Thus, the voltage of the output line can sharply be raised by the fourth transistor, and the bootstrap switch can swiftly be turned off.

When the voltage of the switching terminal is raised, if the drain voltage of the first transistor may not be able to rise accordingly, the bootstrap switch may erroneously be turned on. In the configuration, the drain voltage of the second transistor, that is, the gate voltage of the fourth transistor, is also delayed in a situation where the drain voltage of the first transistor is delayed, and the fourth transistor is thus turned on. This can maintain the high voltage of the output line and prevent the bootstrap switch from erroneously being turned on. That is, the bootstrap switch is turned off when the switching terminal is shifted, enabling safe operation.

In an embodiment, the level shifter may be configured to make a change rate of the drain voltage of the second transistor lower than a change rate of the voltage of the output line. This can more surely maintain the off state of the fourth transistor and prevent the bootstrap switch from erroneously being turned on when the voltage of the switching terminal is shifted.

In an embodiment, a resistance value of the third resistance may be larger than a resistance value of the first resistance. This can more surely maintain the off state of the fourth transistor and prevent the bootstrap switch from erroneously being turned on when the voltage of the switching terminal is shifted.

In an embodiment, a size of the second transistor may be larger than a size of the first transistor. This can more surely maintain the off state of the fourth transistor and prevent the bootstrap switch from erroneously being turned on when the voltage of the switching terminal is shifted.

In an embodiment, the level shifter may further include a second capacitor connected to the drain of the second transistor. This can more surely maintain the off state of the fourth transistor and prevent the bootstrap switch from erroneously being turned on when the voltage of the switching terminal is shifted.

In an embodiment, the switching circuit may be integrated into one semiconductor substrate. The “integration” includes a case in which all of the constituent elements of the circuit are formed on the semiconductor substrate and a case in which main constituent elements of the circuit are integrated.

Part of the resistances, capacitors, and other components for adjusting the circuit constants may be provided outside the semiconductor substrate. Integrating the circuit on one chip makes it possible to reduce the circuit area and also keep the characteristics of the circuit elements uniform.

A control circuit of a DC/DC converter according to an embodiment may include one of the switching circuits described above and a feedback controller that performs feedback control of the switching circuit to bring a state of the DC/DC converter close to a target state.

### (Embodiment)

A preferred embodiment will now be described with reference to the drawings. The same signs are provided to the same or equivalent constituent elements, members, and processes illustrated in the drawings, and duplicate description will appropriately be omitted. The embodiment is exemplary, and not intended to limit the technology. All features and combinations of the features described in the embodiment may not be essential for the technology.

In the present specification, a “state in which a member A and a member B are connected to each other” includes a case in which the member A and the member B are physically and directly connected to each other as well as a case in which the member A and the member B are indirectly connected to each other through another member that does not substantially affect their electrical connection state and that does not impair the functions and the effects obtained by coupling them.

Similarly, a “state in which a member C is provided between a member A and a member B” includes a case in which the member A and the member C or the member B and the member C are directly connected to each other as well as a case in which they are indirectly connected to each other through another member that does not substantially affect their electrical connection state and that does not impair the functions and the effects obtained by coupling them.

In addition, a state in which “a signal A (voltage, current) corresponds to a signal B (voltage, current)” means that the signal A is correlated with the signal B, and specifically, it represents (i) a case in which the signal A is the signal B, (ii) a case in which the signal A is proportional to the signal B, (iii) a case in which the signal A is obtained by the level of the signal B being shifted, (iv) a case in which the signal A is obtained by the signal B being amplified, (v) a case in which the signal A is obtained by the signal B being inverted, or (vi) any combination of these. Those skilled in the art will understand that the range of “corresponding” is determined according to the type and the usage of the signals A and B.

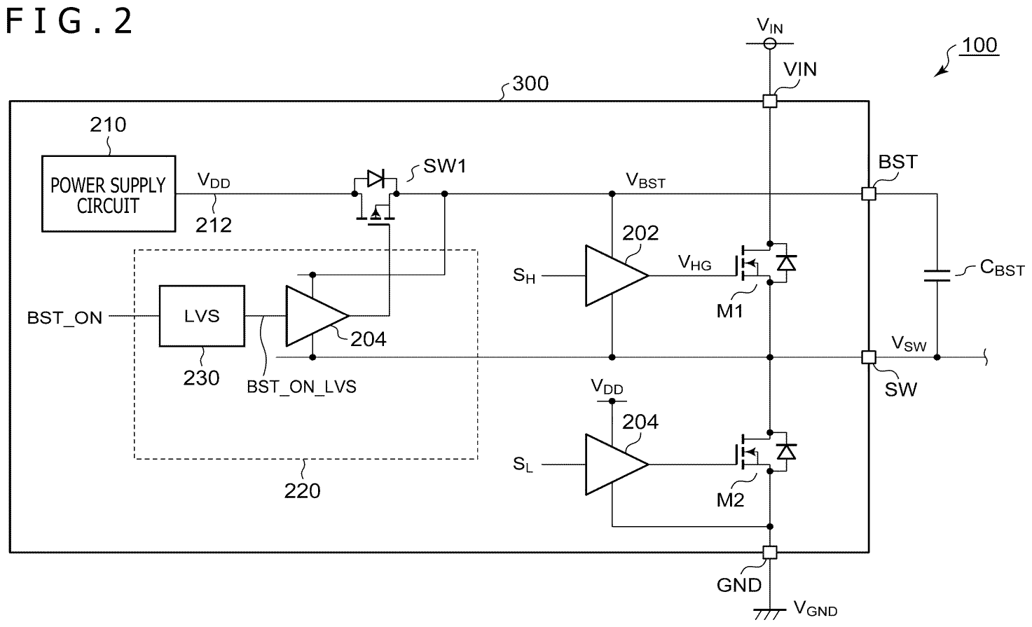

FIG. 2 is a circuit diagram of a switching circuit 200 according to a first embodiment. The switching circuit 200 includes a high side transistor M1, a low side transistor M2, a high side driver 202, a low side driver 204, a bootstrap capacitor C_{BST}, a bootstrap switch SW1, a power supply circuit 210, and a driver circuit 220.

Among the constituent parts of the switching circuit 200, the bootstrap capacitor C_{BST} is externally attached, and the rest of the parts are integrated into a control circuit 300 that is an integrated circuit. Note that discrete elements may be adopted as the high side transistor M1 and the low side transistor M2 and externally attached to the control circuit 300.

A DC voltage (input voltage) VIN from the outside is supplied to an input (VIN) terminal. A ground (GND) terminal is grounded. A load, an inductor, and a transformer that are not illustrated are connected to a switching (SW) terminal. The switching circuit 200 generates, at the switching terminal SW, a switching signal V_{SW} that is switched between high (V_{IN}) and low (V_{GND}).

The bootstrap capacitor C_{BST} is externally attached between a bootstrap (BST) terminal and the SW terminal. The high side transistor M1 is provided between the VIN terminal and the SW terminal. The low side transistor M2 is provided between the SW terminal and the GND terminal.

Although the high side transistor M1 and the low side transistor M2 are metal oxide semiconductor field effect transistors (MOSFETs) in the embodiment, the type of transistors is not limited, and insulated gate bipolar transistors (IGBTs) or bipolar transistors may also be used. The high side driver 202 drives the high side transistor M1 according to a high side pulse S_{H}. A power supply side terminal of the high side driver 202 is connected to the BST terminal, and receives a voltage V_{BST}. A ground side terminal of the high side driver 202 is connected to the SW terminal, and receives a switching voltage V_{SW}. The low side driver 204 drives the low side transistor M2 according to a low side pulse S_{L}.

The power supply circuit 210 generates a power supply voltage V_{DD} for bootstrap and supplies the power supply voltage V_{DD} to a constant voltage line 212. The configuration of the power supply circuit 210 is not particularly limited to any kind, and the power supply circuit 210 may be, for example, a linear regulator. The power supply voltage V_{DD} may be generated by a power supply circuit outside the control circuit 300.

The bootstrap switch SW1 is connected to the constant voltage line 212 and the BST terminal. The bootstrap switch SW1 is a PMOS transistor. The source of the bootstrap switch SW1 is connected to the BST terminal, and the drain of the bootstrap switch SW1 is connected to the constant voltage line 212.

The driver circuit 220 drives the bootstrap switch SW1 according to a control signal BST_ON. Specifically, the bootstrap switch SW1 is turned on in a period in which the low side transistor M2 is on, that is, a period in which the switching voltage V_{SW} is low (0 V). The bootstrap switch SW1 is turned off in a period in which the low side transistor M2 is off, that is, a section in which the switching voltage V_{SW} is high (V_{IN}) or the switching terminal SW has high impedance. Hence, the logic level of the control signal BST_ON is the same as the logic level of the control signal S_{L} for the low side transistor M2.

The driver circuit 220 includes a level shifter 230 and a buffer 240. The level shifter 230 shifts the level of the control signal BST_ON. The buffer 240 drives the bootstrap switch SW1 according to a control signal BST_ON_LVS that has undergone the level shift.

This completes the description of the configuration of the switching circuit 200. Next, a specific configuration of the driver circuit 220 will be described.

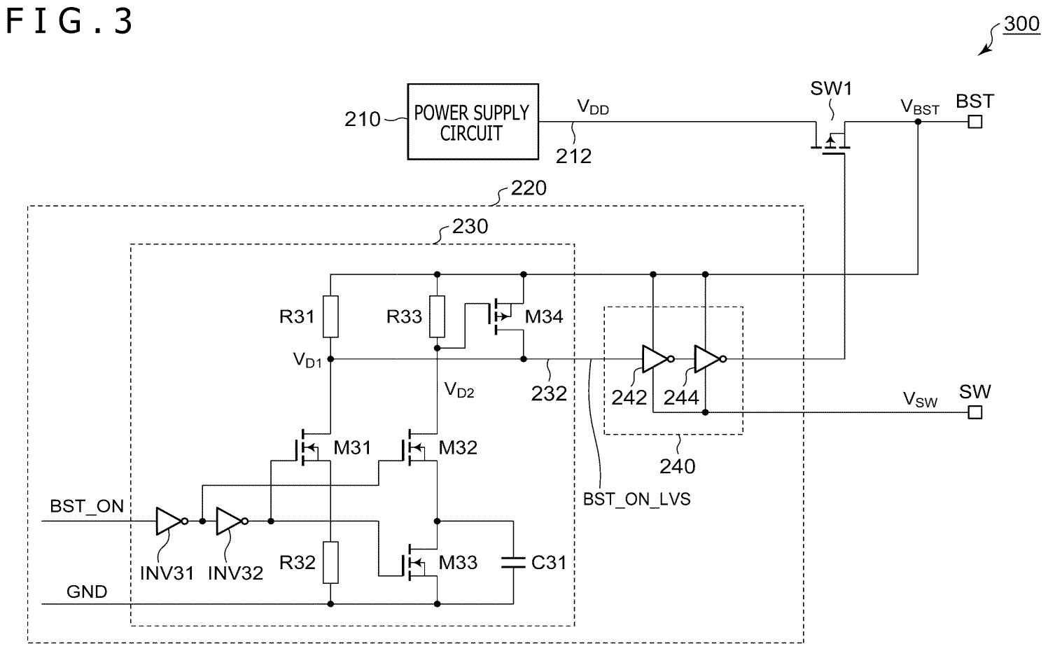

FIG. 3 is a circuit diagram of the control circuit 300 according to the embodiment. An output line 232 of the level shifter 230 is connected to an input node of the buffer 240. The level shifter 230 includes first to fourth transistors M31 to M34, first to third resistances R31 to R33, a first capacitor C31, and inverters INV31 and INV32.

The first resistance R31 is connected to the BST terminal and the output line 232. The first transistor M31 is an NMOS transistor. The drain of the first transistor M31 is connected to the output line 232, and the gate of the first transistor M31 is connected such that the first transistor M31 is turned on when the control signal BST_ON is in the on level (high). In the example, an output signal of the inverter INV32 in the same logic level as the control signal BST_ON is input to the gate of the first transistor M31. The second resistance R32 is connected to the source of the first transistor M31 and the ground.

A first end of the third resistance R33 is connected to the BST terminal. The second transistor M32 is an NMOS transistor. The drain of the second transistor M32 is connected to a second end of the third resistance R33, and the gate of the second transistor M32 is connected such that the second transistor M32 is turned on when the control signal BST_ON is in the off level. In the example, an output signal of the inverter INV31 in the logic level opposite to that of the control signal BST_ON is input to the gate of the second transistor M32. The third transistor M33 is an NMOS transistor. The third transistor M33 is connected to the source of the second transistor M32 and the ground, and the gate of the third transistor M33 is connected such that the third transistor M33 is turned on when the control signal BST_ON is in the on level. In the example, an output signal of the inverter INV32 in the same logic level as the control signal BST_ON is input to the gate of the third transistor M33.

The first capacitor C31 is connected to the third transistor M33 in parallel. That is, a first end of the first capacitor C31 is grounded, and a second end of the first capacitor C31 is connected to the drain of the third transistor M33.

The fourth transistor M34 is a PMOS transistor. The source of the fourth transistor M34 is connected to the BST terminal, and the drain of the fourth transistor M34 is connected to the output line 232. The gate of the fourth transistor M34 is connected to the drain of the second transistor M32.

The buffer 240 includes, for example, two inverters 242 and 244.

This completes the description of the configuration of the switching circuit 200. An advantage of the switching circuit 200 will become clearer by comparison with comparative techniques. Hence, the comparative techniques examined by the present inventor will be described before description will be given of the operation of the switching circuit 200.

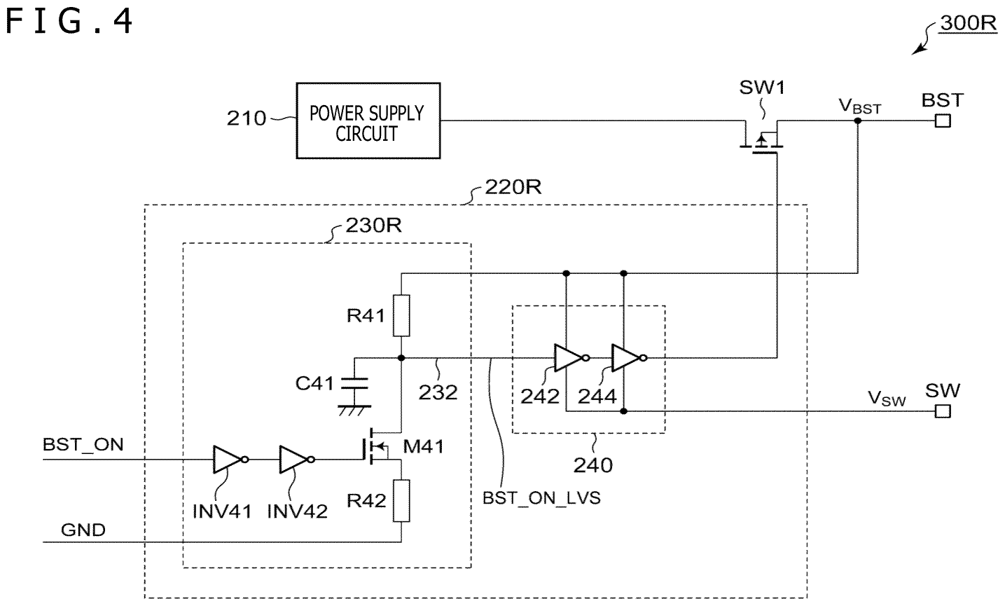

FIG. 4 is a circuit diagram of a control circuit 300R according to comparative technique 1. A driver circuit 220R includes a level shifter 230R and the buffer 240.

The level shifter 230R includes a resistance R41, an NMOS transistor M41, a resistance R42, and inverters INV41 and INV42. The NMOS transistor M41 is turned on when the control signal BST_ON enters the on level (high). As a result, the charge of the output line 232 is discharged by the current flowing through the NMOS transistor M41, and the voltage BST_ON_LVS of the output line 232 becomes low.

The NMOS transistor M41 is turned off when the control signal BST_ON enters the off level (low). As a result, the charge is supplied to the output line 232 by the current flowing through the resistance R41, and the voltage BST_ON_LVS of the output line 232 becomes high.

There is a parasitic capacitance C41 at the drain of the NMOS transistor M41, the parasitic capacitance C41 including a capacitance between the drain and the source and a capacitance between the drain and the substrate. The parasitic capacitance C41 and the resistance R41 form a capacitor-resistor (CR) circuit, and the time constant of the CR circuit limits the turn-off time of the bootstrap switch SW1. Hence, fast switching is difficult (problem 1).

When the voltage V_{SW} of the switching terminal SW rises, the voltage V_{BST} of the BST terminal also rises in association with the voltage V_{SW}. On the other hand, the drain voltage of the NMOS transistor M41, that is, the voltage of the output line 232, may not be able to follow the switching voltage V_{SW} and the voltage V_{BST} of the BST terminal and rises late due to the influence of the parasitic capacitance C41 of the NMOS transistor M41. As a result, the bootstrap switch SW1 may erroneously be turned on (problem 2).

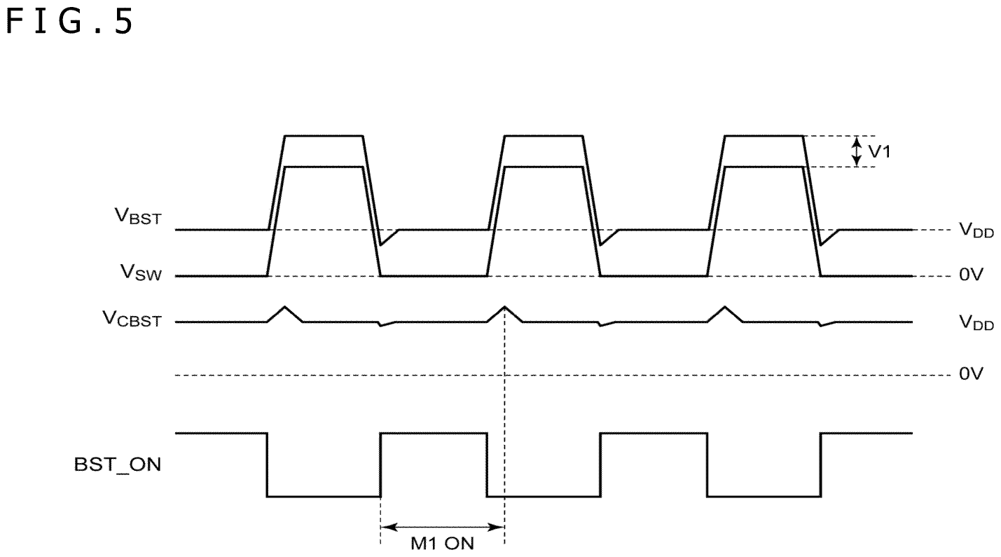

FIG. 5 is an operation waveform diagram of the control circuit 300R according to comparative technique 1. It is assumed that the control signal BST_ON becomes high when the low side transistor is on. Consequently, there is a delay before the bootstrap switch SW1 is turned off after the BST_ON signal is switched to low, and the bootstrap switch SW1 continues to be on during the rise of the switching voltage V_{SW} in some cases. As a result, a reverse current may be generated from the BST terminal to the constant voltage line 212. There may be such a problem that the voltage between the BST terminal and the SW terminal is changed or the power supply voltage V_{DD} is overshot (problem 3).

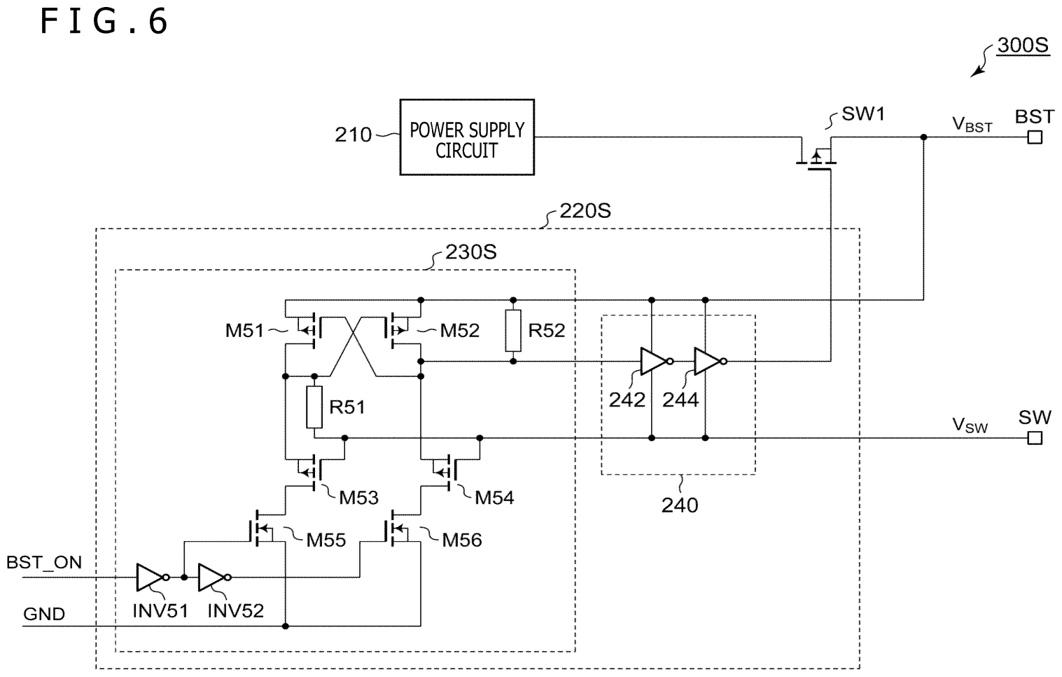

FIG. 6 is a circuit diagram of a control circuit 300S according to comparative technique 2. A driver circuit 220S includes a level shifter 230S and the buffer 240. The level shifter 230S includes transistors M51 to M56, resistances R51 and R52, and inverters INV1 and INV2. The configuration is fast as compared to the level shifter 230R of FIG. 5, and the problems 1 to 3 can be solved. However, the transistors M53, M54, M55, and M56 may need to include high breakdown voltage elements. There is accordingly a problem that the chip area is enlarged, and the cost is increased.

An operation of the control circuit 300 of the embodiment will be described.

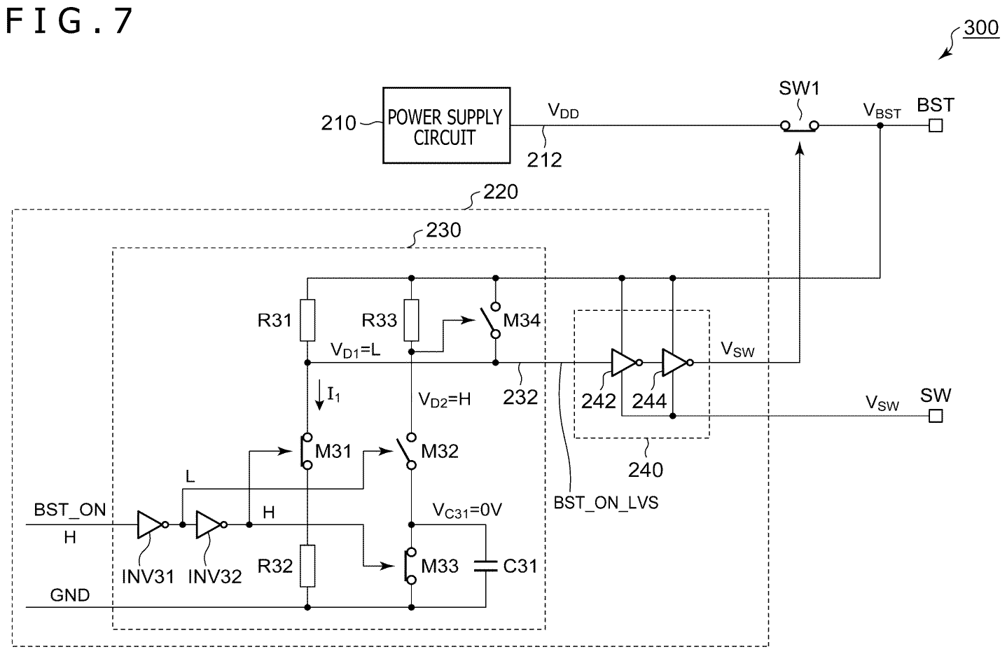

FIG. 7 is an equivalent circuit diagram of the control circuit 300 when the control signal BST_ON is in the on level (high).

The first transistor M31 is turned on when the control signal BST_ON enters the on level (high). As a result, a current I₁ flows through the first transistor M31 and the second resistance R32. The charge of the output line 232 and the first transistor M31 is discharged, and a drain voltage V_{D1} of the first transistor M31, that is, the voltage BST_ON_LVS of the output line 232, becomes low. As a result, the bootstrap switch SW1 is turned on.

On the other hand, the second transistor M32 is off, and the drain of the second transistor M32 is pulled up by the third resistance R33. As a result, a drain voltage V_{D2} becomes high (V_{BST}), and the fourth transistor M34 is turned off.

In this case, the second transistor M32 is turned off, and the third transistor M33 is turned on. As the third transistor M33 is turned on, the first capacitor C31 is discharged, and a voltage V_{C31} of the first capacitor C31 becomes 0 V.

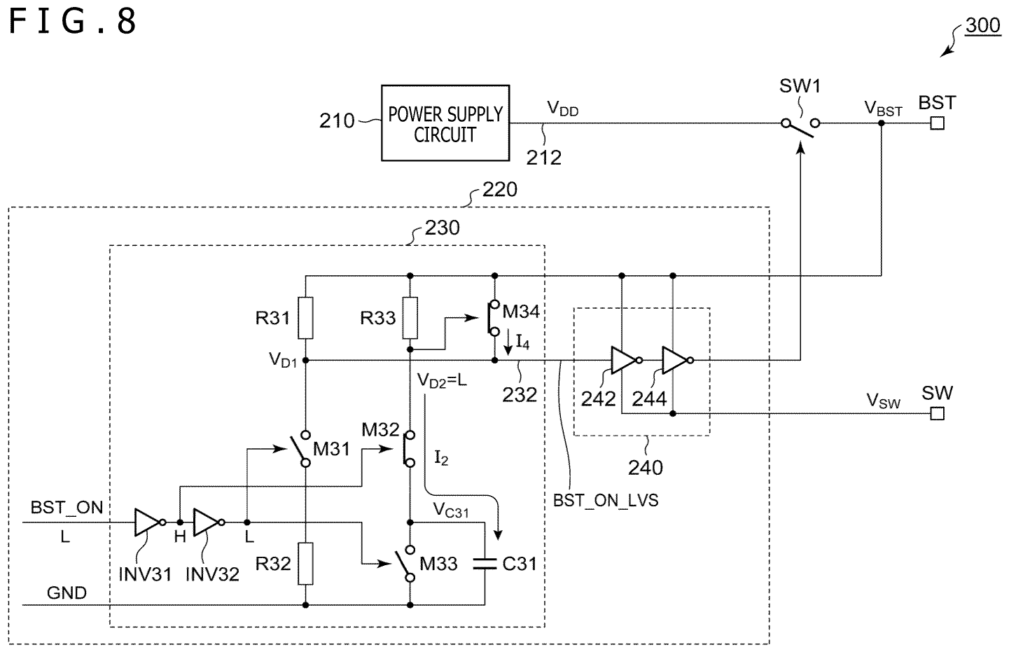

FIG. 8 is an equivalent circuit diagram of the control circuit 300 when the control signal BST_ON is in the off level (low). When the control signal BST_ON is shifted to the off level (low), the first transistor M31 is turned off, and the output line 232 is pulled up by the first resistance R31. The drain voltage V_{D1} of the first transistor M31, that is, the voltage BST_ON_LVS of the output line 232, would rise toward the voltage V_{BST} of the BST terminal when the output line 232 is pulled up by the first resistance R31. However, the contribution of the current flowing through the first resistance R31 to the rise of the voltage BST_ON_LVS is small, and the voltage BST_ON_LVS is raised by the current flowing through the fourth transistor M34 as described below.

When the control signal BST_ON is in the off level, the third transistor M33 is turned off, and the second transistor M32 is turned on. As a result, the first capacitor C31 is charged by a current I₂ flowing through the second transistor M32. The charge current I₂ is supplied from the drain of the second transistor M32, and the drain voltage V_{D2} of the second transistor M32, that is, the gate voltage of the fourth transistor M34, swiftly drops. As a result, the fourth transistor M34 is instantaneously turned on. The impedance of the fourth transistor M34 is lower than the impedance of the first resistance R31, and the capacitance of the output line 232 and the drain of the first transistor M31 is charged by a current 14 flowing through the fourth transistor M34. As a result, the drain voltage V_{D1}, that is, the voltage BST_ON_LVS of the output line 232, can sharply be raised, and the bootstrap switch SW1 can swiftly be turned off.

This completes the description of the operation of the switching circuit 200.

According to the configuration, the bootstrap switch SW1 can be switched fast, and the problems 1 and 3 can be solved.

Here, the first transistor M31 and the second transistor M32 include the same type of elements, and similar parasitic capacitances are provided to the drains. When the switching voltage V_{SW} is raised, the drain voltage of the first transistor M31 may not be able to rise accordingly. However, the drain voltage of the second transistor M32 also may not be able to rise accordingly. Therefore, the fourth transistor M34 is turned on, and the output line 232 is fixed to the voltage V_{BST} of the BST terminal. As a result, the bootstrap switch SW1 can be turned off when the switching voltage V_{SW} is shifted. That is, the problem 2 can also be solved.

In FIG. 3, only the first transistor M31 and the second transistor M32 have to include high breakdown voltage elements, and the others can include low breakdown voltage elements. Accordingly, although the chip area is larger than that in comparative technique 1 (FIG. 4), the chip area can be smaller than that in comparative technique 2 (FIG. 6).

Next, more preferable configurations and modifications of the switching circuit 200 will be described.

The change rate of the drain voltage V_{D2} of the second transistor M32 (gate voltage of the fourth transistor M34) can be lower than the change rate of the drain voltage V_{D1} of the first transistor M31 (voltage of the output line 232). In this way, the drain voltage V_{D2} of the second transistor M32 (gate voltage of the fourth transistor M34) rises later than the voltage of the output line 232 at the rise of the switching voltage V_{SW}, and the fourth transistor M34 can surely be turned on. This can more surely solve the problem 2.

For example, the resistance value of the third resistance R33 may be larger than the resistance value of the first resistance R31.

Alternatively, the size of the second transistor M32 may be larger than the size of the first transistor M31. In this way, the parasitic capacitance of the drain of the second transistor M32 becomes larger than the parasitic capacitance of the drain of the first transistor M31, and the change rate of the drain voltage of the second transistor M32 can be relatively low.

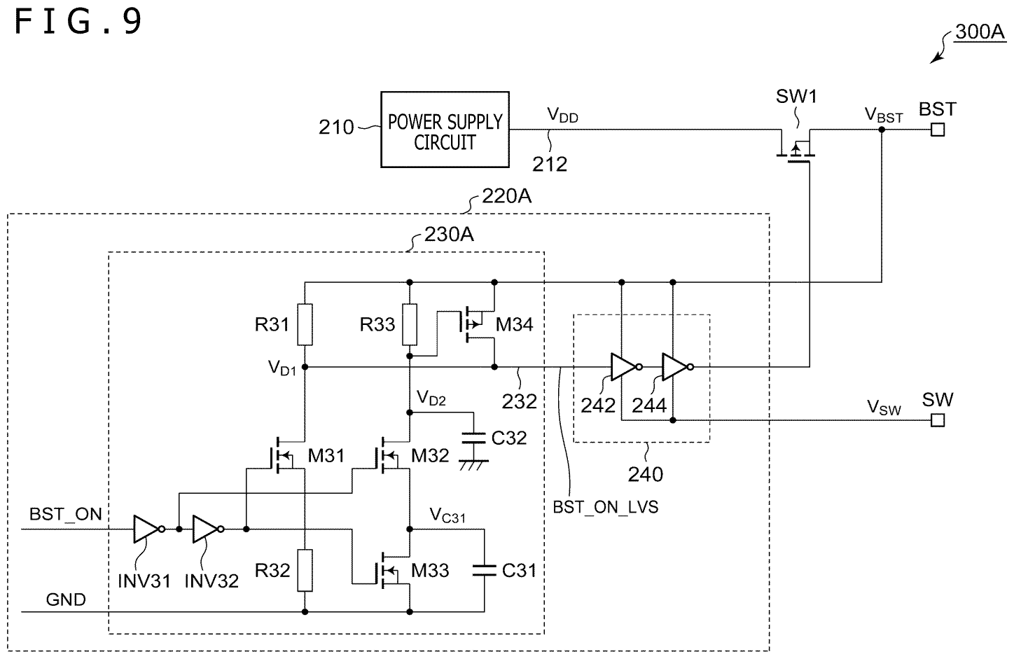

FIG. 9 is a circuit diagram of a control circuit 300A according to a modification. A level shifter 230A includes a second capacitor C32 connected to the drain of the second transistor M32. The second capacitor C32 can make the change rate of the drain voltage V_{D2} of the second transistor M32 (gate voltage of the fourth transistor M34) lower than the change rate of the drain voltage V_{D1} of the first transistor M31 (voltage of the output line 232).

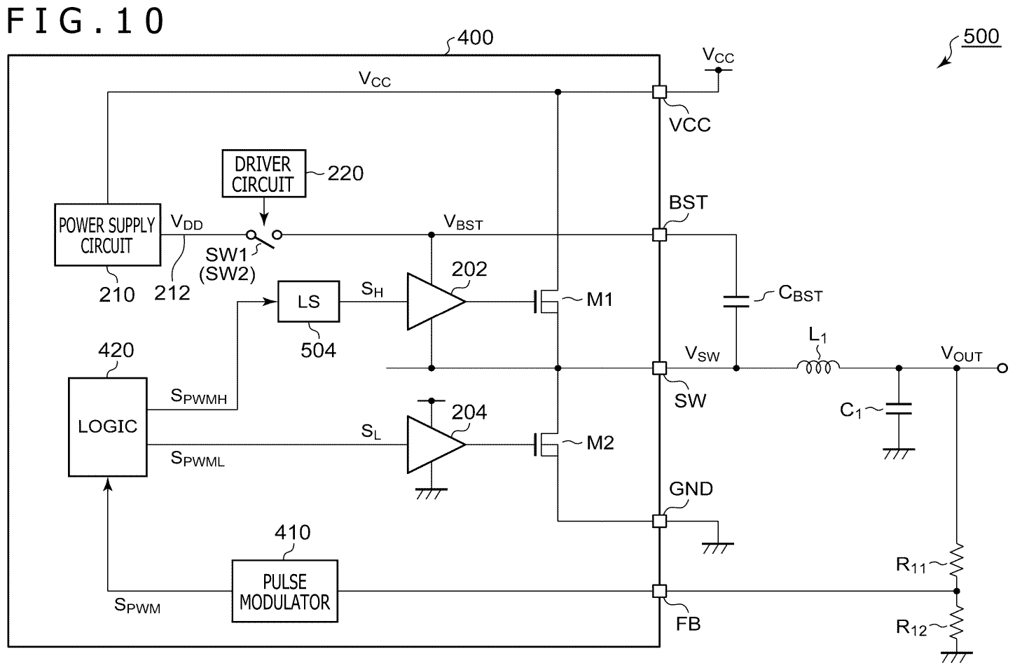

Next, the usage of the switching circuit 200 will be described. The switching circuit 200 can be used for, for example, a DC/DC converter. FIG. 10 is a circuit diagram of a DC/DC converter 500. The DC/DC converter 500 includes a control circuit 400, the bootstrap capacitor C_{BST}, an inductor L₁, an output capacitor C₁, and resistances R₁₁ and R₁₂. The control circuit 300 is a functional integrated circuit (IC) integrated into one semiconductor substrate.

The DC/DC converter 500 is a constant voltage output converter, and supplies an output voltage V_{OUT} stabilized at a predetermined level to an unillustrated load. A feedback signal V_{FB} obtained by the output voltage V_{OUT} of the DC/DC converter 500 being divided with use of the resistances R₁₁ and R₁₂ is input to a feedback (FB) terminal of the control circuit 300. The feedback signal V_{FB} corresponding to the output current is fed back in the constant current output converter.

A pulse modulator 410 generates a pulse signal S_{PWM} for instructing on/off of the high side transistor M1 to bring the feedback signal V_{FB} close to a target value V_{REF}. A logic circuit 420 generates pulse signals S_{PWMH} and S_{PWML} for controlling the high side transistor M1 and the low side transistor M2, respectively, according to the pulse signal S_{PWM}. The pulse signal S_{PWMH} of the high side is converted into the high side pulse S_{H} by a level shifter 504 and supplied to the high side driver 202. The pulse signal S_{PWML} of the low side is supplied as the low side pulse S_{L} to the low side driver 204.

The usage of the switching circuit 200 is not limited to the DC/DC converter. The switching circuit 200 can also be used for a power converter, such as an inverter and a converter, and can also be applied to a motor driver.

The embodiments are illustrative, and those skilled in the art will understand that there can be various modifications for the combinations of the constituent elements and the processes of the embodiments and that the modifications are also included in the scope of the present disclosure or the present technology.

What is claimed is:

1. A switching circuit comprising:
an input terminal;
a switching terminal;
a ground terminal;
a bootstrap terminal;
a high side transistor connected to the input terminal and the switching terminal;
a low side transistor connected to the switching terminal and the ground terminal;
a bootstrap capacitor connected to the switching terminal and the bootstrap terminal;
a bootstrap switch including a P-channel metal oxide semiconductor transistor connected to a constant voltage line and the bootstrap terminal; and
a driver circuit that turns on the bootstrap switch in a period in which the low side transistor is on and that turns off the bootstrap switch in a period in which the low side transistor is off, wherein
the driver circuit includes
a level shifter that shifts a level of a control signal, and
a buffer that drives the P-channel metal oxide semiconductor transistor according to output of the level shifter, and
the level shifter includes
an output line,
a first resistance connected to the bootstrap terminal and the output line,
a first transistor including a drain connected to the output line, the first transistor being turned on when the control signal is in an on level,
a second resistance connected to a source of the first transistor and a ground,
a third resistance including a first end connected to the bootstrap terminal,
a second transistor including a drain connected to a second end of the third resistance, the second transistor being turned on when the control signal is in an off level,
a third transistor connected to a source of the second transistor and the ground and turned on when the control signal is in the on level,
a first capacitor connected to the third transistor in parallel, and
a fourth transistor including a source connected to the bootstrap terminal, a drain connected to the output line, and a gate connected to a drain of the second transistor.

2. The switching circuit according to claim 1, wherein
a change rate of a drain voltage of the second transistor is lower than a change rate of a voltage of the output line.

3. The switching circuit according to claim 1, wherein
a resistance value of the third resistance is larger than a resistance value of the first resistance.

4. The switching circuit according to claim 1, wherein
a size of the second transistor is larger than a size of the first transistor.

5. The switching circuit according to claim 1, wherein
the level shifter further includes a second capacitor connected to the drain of the second transistor.

6. The switching circuit according to claim 1, wherein
the switching circuit is integrated into one semiconductor substrate.

7. A control circuit of a direct current/direct current converter, the control circuit comprising:
the switching circuit according to claim 1; and
a feedback controller that performs feedback control of the switching circuit to bring a state of the direct current/direct current converter close to a target state.

8. A direct current/direct current converter comprising:
the control circuit according to claim 7.
